(19) United States
(12) Patent Application Publication
(10) Pub. No.: US 2015/0226805 A1
(43) Pub. Date: Aug. 13, 2015

(54) SYSTEMS, DEVICES, AND METHODS FOR MOTOR MONITORING

(71) Applicant: Nidec Motor Corporation, St. Louis, MO (US)

(72) Inventors: Timothy R. Albers, St. Louis, MO (US); Helmuth M. Glatt, St. Louis, MO (US); Gregory E. Levine, St. Louis, MO (US); Gregory A. Peterson, Elgin, IL (US); Christopher T. Wiseman, St. Louis, MO (US); Michael P. Sullivan, Elgin, IL (US); David M. Lyle, Chesterfield, MO (US)

(21) Appl. No.: 14/615,904

(22) Filed: Feb. 6, 2015

Related U.S. Application Data
(60) Provisional application No. 61/937,319, filed on Feb. 7, 2014.

(51) Int. Cl. G01R 31/34; G05B 23/02; G01S 19/31; G08B 25/08

(52) U.S. Cl. CPC G01R 31/34; G08B 25/08; G05B 23/0208; G01S 19/31

(57) ABSTRACT

A data acquisition device that can be coupled with any motor, even those already in service, to automatically monitor the operation of the motor and provide alerts when the motor is in need of repair or replacement. The data acquisition device senses conditions of the motor and transmits sensor data to a computer system or other remote monitoring device so that the remote monitoring device can determine if the motor needs to be repaired or replaced. The data acquisition device also acquires location data and sends it to the remote monitoring device so that a technician or other person can quickly locate the motor.

### RELATED APPLICATION

The present application is a non-provisional patent application and claims priority benefit, with regard to all common subject matter, of earlier-filed U.S. provisional patent application titled “SYSTEMS, DEVICES, AND METHODS FOR MOTOR MONITORING”, Ser. No. 61/937,319, filed on Feb. 7, 2014, incorporated by reference in its entirety into the present application.

### BACKGROUND

The present invention relates to systems, devices, and methods for monitoring the operation of electric motors, components driven by the electric motors, and/or devices separate from the electric motors.

Electric motors are used in a variety of applications such as HVAC systems, pumping stations, appliances, material handling systems, etc. The motors, components driven by the motors, and even related devices separate from the motors occasionally need to be repaired and replaced. Electric motors that are in need of repair or replacement often exhibit symptoms such as excess vibrations, high heat, excessive current draw, etc., but many people don't notice the symptoms and only become aware of needed repairs or replacement after the motors have shut down completely. This is inconvenient when the motors are used in non-critical applications and potentially dangerous when the motors are used in more critical applications.

Motors used in super critical operations often include integral motor controllers that are monitored and controlled by manned central control stations. This provides immediate notification when a motor is in need of repair or replacement, but monitoring motors in this way is expensive and labor intensive and therefore not economically suitable for most motor applications. Thus, many motors are either not monitored at all or are monitored manually by a technician or maintenance person who occasionally observes the motors to see if they appear to be operating normally. Such manual monitoring is inaccurate and often fails to identify motors in need of repair until they shut down completely.

Accordingly, there is a need for an improved way to monitor electric motors that overcomes the limitations of the prior art.

### SUMMARY

The present invention solves the above-described problems and provides a distinct advance in the art of motor monitoring. Embodiments of the invention provide for the automatic monitoring of electric motors without the use of integral motor controllers, dedicated central control stations, and the costs and complexities associated with such prior art monitoring systems and without requiring frequent manual inspections by technicians or other motor operators or owners.

One embodiment of the invention is a data acquisition device that can be coupled with any motor, even a motor that has already been placed in service, to automatically monitor the operation of the motor and provide alerts when the motor is in need of repair or replacement. The data acquisition device senses conditions of the motor and transmits sensor data to a remote monitoring device so that the remote monitoring device can determine if the motor needs to be repaired or replaced. The sensor data may also be used for data collection and analysis purposes. The data acquisition device also acquires location data for the motor and sends it to the remote monitoring device along with the sensor data so that a technician or other person can quickly locate the motor if the motor requires repair or replacement.

An embodiment of the data acquisition device broadly comprises: a location determining component; at least one sensor; a communication device; control unit; and a power source. Some of these components may be mounted in or on a housing or circuit board that may be attached to a motor to be monitored. Or, the components may be stand-alone components or even part of the motor that is monitored.

For example, in one embodiment, the data acquisition device includes a housing for its control unit and a number of wireless or wired serial ports or other input ports for coupling with the location determining component, the sensors, and the communication unit, all or some of which may be mounted at locations remote from the control device. The data acquisition device may also include a power input for coupling with the power source, which may also be mounted away from the control unit. Such a modular design allows additional sensors and other components to be coupled with the data acquisition device before or after the data acquisition device is placed in service.

In another embodiment, the control unit, the location determining component, the sensors, the communication device, and the power source are all integrally mounted in a single housing so that the data acquisition device requires no external wiring or serial communication ports.

The location determining component determines the location of the motor and generates corresponding location data that is sent to the remote monitoring device. The location data permits a technician or other person to quickly and easily locate a motor in need of repair or replacement. The location determining component may be integrated into the data acquisition device or may be a separate component that is coupled with the device as explained above. In one embodiment, the location determining component is a global navigation satellite system receiver.

In some embodiments, the data acquisition device may also include a visual or audible indicator such as an LED light, beeper, etc. that is triggered whenever its control unit receives sensor data that suggests the motor is in need of repair or replacement. The visual or audible indicator, along with the location determining component, helps the technician or other person to find the motor when multiple motors are installed in the same approximate geographic location.

The sensor senses a condition of the motor or a component driven by the motor and generates sensor data that is then sent to the remote monitoring device. Any number of sensors may be integrated into or coupled with the data acquisition device. The sensors may employ any known sensing technologies and may sense conditions of the monitored motor or components driven by the motor such as fans, pumps, valves, etc. The sensors may also be coupled with devices that are completely independent of the motor. This allows the data acquisition device to act as a data relay for other devices in the vicinity of the motor. The sensors may include vibration sensors, temperature sensors, current sensors, voltage sensors, power sensors, motor speed sensors, fluid pressure sensors, fluid flow sensors, motor flux sensors, or valve position sensors.

The control unit receives the location data from the location determining component and the sensor data from the sensor or sensors and instructs the communication device to transmit at least portions of the data to the remote monitoring device. The control unit may automatically transmit the data at prescribed intervals or may transmit the data only if the control unit and/or the sensors determine the sensor data deviates from a selected threshold range. The control unit may consist of any number of processors, integrated circuits, application specific integrated circuits, or any other electronic devices or components.

The communication device transmits the sensor data and location data to the remote monitoring device under the direction of the control unit. In one embodiment, the communication device is a cellular phone transmitter. In other embodiments, the communication device may be a peer-to-peer network transmitter or any other wired or wireless transmitter of data.

The power source is provided for powering the other components of the data acquisition device and preferably requires no external wiring. In one embodiment, the power source is a power scavenging flux coil that may be placed on or near an electrical input to the electric motor that is being monitored to generate electricity from magnetic fields generated by the motor. This enables the power source to power the other components of the data acquisition device without a direct connection to the source of electricity. The power source may alternatively include a current transformer, a battery, or a capacitor.

The above-described data acquisition device may be mounted on or near any electric motor, including those already in service. The data acquisition device continuously or periodically develops sensor data and location data and transmits it to the remote monitoring device. Because the data acquisition device can be powered by a power scavenging coil and transmits location data and sensor data wirelessly, it requires no external source of power or control wiring.

The remote monitoring device may be any device capable of receiving the sensor data and location data transmitted from the data acquisition device and analyzing the data to predict when the monitored motor requires repair or replacement. In one embodiment, the remote monitoring device is a web server that may be accessed by technicians and other via the Internet or other communications channel. In other embodiments, the remote monitoring device is a mobile phone or other portable electronic device that receives texts and other messages directly from the data acquisition device.

This summary is provided to introduce a selection of concepts in a simplified form that are further described in the detailed description below. This summary is not intended to identify key features or essential features of the claimed subject matter, nor is it intended to be used to limit the scope of the claimed subject matter. Other aspects and advantages of the present invention will be apparent from the following detailed description of the embodiments and the accompanying drawing figures.

### BRIEF DESCRIPTION OF THE DRAWING FIGURES

Embodiments of the present invention are described in detail below with reference to the attached drawing figures, wherein:

FIG. 1 is a schematic diagram of computer equipment and communications networks that may be used to implement embodiments of the present invention.

FIG. 2 is a block diagram of selected components of a data acquisition device constructed in accordance with embodiments of the invention.

The drawing figures do not limit the present invention to the specific embodiments disclosed and described herein. The drawings are not necessarily to scale, emphasis instead being placed upon clearly illustrating the principles of the invention.

### DETAILED DESCRIPTION

The following detailed description of embodiments of the invention references the accompanying drawings. The embodiments are intended to describe aspects of the invention in sufficient detail to enable those skilled in the art to practice the invention. Other embodiments can be utilized and changes can be made without departing from the scope of the claims. The following detailed description is, therefore, not to be taken in a limiting sense. The scope of the present invention is defined only by the appended claims, along with the full scope of equivalents to which such claims are entitled.

In this description, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the present technology can include a variety of combinations and/or integrations of the embodiments described herein.

The present invention provides systems, devices, and methods for monitoring the operation of electric motors, components driven by the electric motors, and/or devices separate from the electric motors and for providing notification of needed motor repair and/or possible motor failure without the use of integral motor controllers, dedicated central control stations, and the costs and complexities associated with such prior art monitoring systems. The invention may also be used for data collection, analysis, and similar purposes.

The present invention may monitor any number and type of motors, including motors that are already in service. The motors to be monitored may operate on direct current (DC) or alternating current (AC), may be synchronous or asynchronous, and may be single phase or three phase. The motors may be of any type, including but not limited to, permanent split capacitor (PSC) motors, brushed DC motors, switched reluctance motors, coreless or ironless DC motors, series wound universal motors, induction motors, torque motors, or stepper motors. Moreover, the motors may be fixed speed, multi-speed, or variable speed and may have any horsepower (HP) rating. The principles of the present invention are not limited to any particular motor type, technology, or size. The invention may also monitor the operation of components driven by motors such as pumps, fans, blowers, valves, etc. and even devices separate from the electric motors such as independent thermostats, valves, etc.

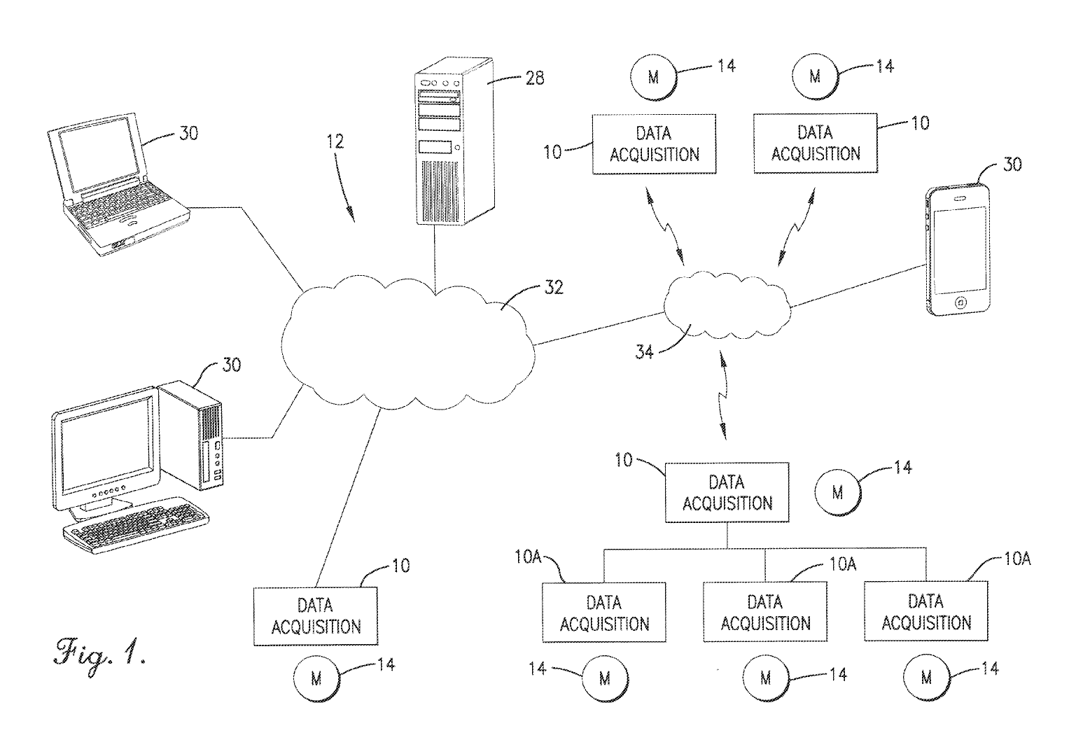

Aspects of the invention may be at least partially implemented with a number of data acquisition devices 10 and a system of computer and communications equipment 12 illustrated in FIG. 1. FIG. 1 shows several data acquisition devices 10 monitoring several electric motors 14, but the principles of the invention are applicable to any number of data acquisition devices and motors.

As described in more detail below, each data acquisition device 10 senses the conditions of one or more motors, components driven by the motor, and/or devices separate from the motors and transmits sensor data to a remote monitoring device that determines if the motor needs to be repaired or replaced. At least one of the data acquisition devices also acquires and transmits location data to the remote monitoring device so that technicians or other people can find a motor in need of repair or replacement.

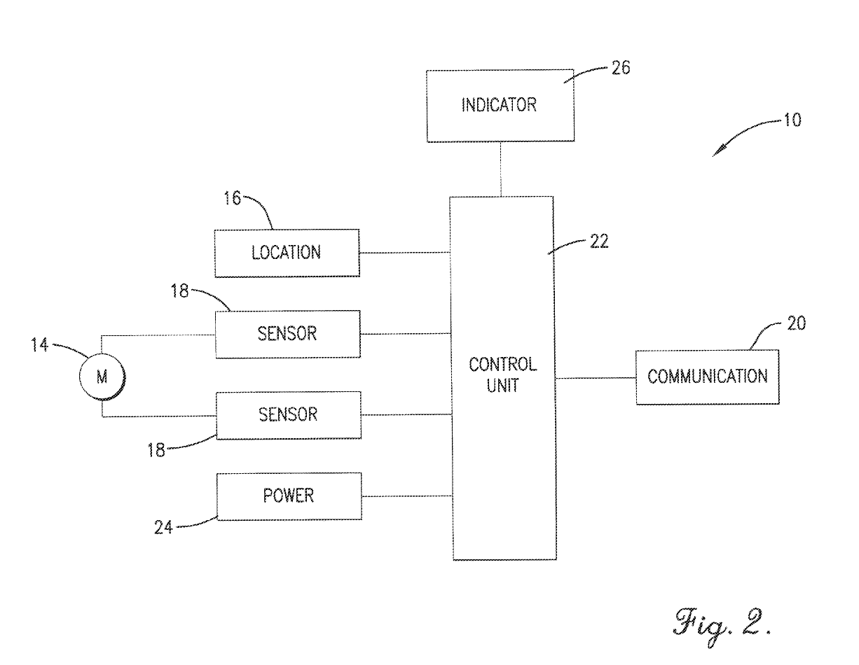

An embodiment of one of the data acquisition devices 10 is illustrated in FIG. 2 and comprises: a location determining component 16; at last one sensor 18; a communication device 20; control unit 22; a power source 24, and an indicator 26. Some of these components may be mounted in or on a housing or circuit board that may be attached to one of the motors 14. Or, the components may be stand-alone components or even part of the motor 14 as discussed below.

In one embodiment, the data acquisition device 10 includes a housing for the control unit 22 and a number of wired or wireless serial ports or other input ports for coupling with the location determining component 16, the sensors 18, and the communication device 20, and the indicator 26, all or some of which may be mounted at locations remote from the control unit 22. This embodiment of the invention may also include a power input for coupling with the power source, which may also be mounted away from the control unit. This embodiment of the invention provides a modular design that allows additional sensors and other components to be coupled with the data acquisition device before or after the data acquisition device is placed in service.

In another embodiment, the control unit 22, the location determining component 16, the sensors 18, the communication device 20, the power source 24, and the indicator 26 are all integrally mounted in a single housing so that the data acquisition device is a single integrated unit with no external wiring or serial communication ports. This embodiment of the invention is more convenient for operators who simply wish to place an integrated unit on or near a motor and obtain the motor monitoring capabilities described herein.

Each of the major components of the data acquisition device 10 will now be discussed in more detail. The location determining component 16 determines a location of the motor 14 and generates corresponding location data that is sent by the communication device 20. The data supplied by the location determining component 16 allows a technician or other person to quickly and easily locate the monitored motor 14 to repair or replace it when needed. The location determining component 16 may be integrated into the data acquisition device 10 or may be a separate component that is coupled with the device as explained above.

The location determining component 16 may be a Global Navigation Satellite System (GNSS) receiver such as a Global Positioning System (GPS) receiver, a GLONASS receiver, a Galileo receiver, or a similar device that is adapted to provide, in a substantially conventional manner, geographic location information for the data acquisition device. In some embodiments, the location determining component may include a high sensitivity GPS receiver to facilitate determination of the geographic coordinates of the data acquisition device when the data acquisition device is shielded from the sky, such as when it is located inside a building. Or, the location determining component, or at least its antenna, may be mounted outside the building and wired to the data acquisition device. The GPS is a satellite-based radio navigation system that allows determination of navigation information, such as position, velocity, time, and direction, for an unlimited number of users. Formally known as NAVSTAR, the GPS incorporates a plurality of satellites that orbit the earth.

The location determining component 16 may include an antenna for receiving signals, such as a GPS patch antenna or quadrifilar helical antenna, and various processing and memory elements to determine the geographic location of the data acquisition device 10. Or, the location determining component 16 may provide information to the remote monitoring device to enable the remote monitoring device to determine the geographic location of the data acquisition device. Thus, the location determining component 16 need not itself calculate the current geographic location of the data acquisition device 10.

The location determining component 16 does not necessarily employ GPS or other GNSS capabilities. For example, the location determining component 16 may receive cellular or other positioning signals utilizing other various methods to facilitate determination of geographic locations without being limited to GPS.

The indicator 26 may be provided along with the location determining component to help a technician locate a motor that needs to be repaired or replaced when the data acquisition device is used in a facility with numerous motors. The indicator is triggered whenever the control unit 22 receives sensor data that suggests the motor is in need of repair or replacement.

In one embodiment, the indicator 26 includes a light-emitting device such as one or more high intensity light-emitting diodes or other lights. In some embodiments, the control unit 22 and/or other circuitry can alter the color, intensity, and/or duty cycle of the light-emitting device to indicate the action needed for a motor. For example, the control unit 22 may trigger a blinking yellow light when the motor 14 needs to be repaired or otherwise serviced and a blinking red light when the motor needs to be replaced.

The indicator 26 may also include an audible device such as a horn, speaker, or alarm or a combination of a light-emitting device and an audible device. The indicator 26 may be positioned anywhere on or near the data acquisition device such that it can be easily seen, heard, or otherwise observed by nearby persons.

The sensors 18 sense conditions of the motor 14, components driven by the motor, and/or devices separate from the motor and generate sensor data that is transmitted to the remote monitoring device. The data acquisition device 10 may include any number of sensors that may be integrated into the device and/or separate components that are coupled with the device. For example, the data acquisition device 10 may include or be coupled with an accelerometer or other vibration sensor, a thermistor or other temperature sensor, a current sensor, a voltage sensor, a power sensor, a speed sensor, a pressure sensor, a flow sensor, and/or a motor flux sensor. The present invention is not limited to any number or type of sensors, but instead can be used with any existing or future sensors.

The data acquisition device 10 may also receive data from devices other than the motor and components driven by the motor and relay the data to the remote monitoring device. For example, the data acquisition device 10 may receive data from a temperature sensor that monitors the ambient temperature inside or outside of a building in which the motor is located and may relay this temperature data to the remote monitoring device.

When the location determining component 16 and/or the sensors 18 are not integrated into a single housing for the data acquisition device 10, they may be hard-wired to the control unit 22 via a 2 or 4 wire RS-232, RS-422, or RS-485 serial interface or may transmit data to the control device via a ZigBee type wireless device.

The control unit 22 receives the location data from the location determining component 16 and the sensor data from the sensors 18 and instructs the communication device 20 to transmit at least portions of the location data and the sensor data to the remote monitoring device as described below. The control unit 22 may periodically transmit the location data and the sensor data or may transmit the data only if the control device determines the sensor data deviates from a selected threshold range. The control unit may consist of any number of processors, integrated circuits, application specific integrated circuits, or any other electronic devices or components.

Functions of the control unit 22 described herein may be implemented by one or more computer programs stored in or on computer-readable medium residing on or accessible by the control unit 22. The computer programs may comprise listings of executable instructions for implementing logical functions in the control unit and can be embodied in any non-transitory computer-readable medium for use by or in connection with an instruction execution system, apparatus, or device, such as a computer-based system, processor-containing system, or other system that can fetch the instructions from the instruction execution system, apparatus, or device, and execute the instructions. In the context of this application, a “computer-readable medium” can be any non-transitory means that can contain, store, or communicate the programs. The computer-readable medium can be, for example, but not limited to, an electronic, magnetic, optical, electro-magnetic, infrared, or semi-conductor system, apparatus, or device. More specific, although not inclusive, examples of the computer-readable medium would include the following: an electrical connection having one or more wires, a portable computer diskette, a random access memory (RAM), a read-only memory (ROM), an erasable, programmable, read-only memory (EPROM or Flash memory), an optical fiber, and a portable compact disk read-only memory (CDROM).

The communication device 20 transmits the sensor and location data to the remote monitoring device under the direction of the control unit 22. In one embodiment, the communication device 22 is a cellular phone transmitter. In other embodiments, the communication device may be a ZigBee type wireless device or other peer-to-peer network transmitter. In still other embodiments, the communication device may be a direct or indirect Internet connection such as a wireless broadband connection, DSL connector, or ISDN connector. However, the invention is not limited to any particular type of communication technology.

Each of the data acquisition devices 10 does not necessarily include its own communication device 20. For example, the data acquisition devices labeled 10 in FIG. 1 may have their own communication devices that transmit location data and sensor data to the remote monitoring device, but the data acquisition devices labeled 10A may not have their own communication devices, but instead may send their location data and sensor data to one of the data acquisition devices 10 that does have a communication device via a peer-to-peer communication channel. The data acquisition device 10 may then relay the location data and the sensor data for the data acquisition devices 10A to the remote monitoring device. The data acquisition devices 10A may also not have location determining components, but instead may be associated with location data for the data acquisition device 10.

The power source 24 is provided for powering the other components of the data acquisition device 10. In one embodiment, the power source is a power scavenging flux coil that may be placed on or near an electrical input to the electric motor 14 so as to generate electricity from magnetic fields generated by the motor. This enables the power source 24 to power the other components of the data acquisition device without wiring the device to a direct source of electricity. The power source 24 may also include a current transformer, a battery, or a capacitor. Because an embodiment of the data acquisition device can be powered by a power scavenging coil and transmits location data and sensor data wirelessly, it requires no external source of power or control wiring. In another embodiment, the power source 24 may share power delivered to the electric motor 14. For example, if the electric motor 14 has an integrated motor controller that operates on DC power, the power source 24 may simply be wired to the power source of the integrated motor controller and receive power therefrom. If the electric motor 14 does not have an integrated motor controller or other component that operates on DC power (i.e. the motor 14 only operates on high voltage AC power), the power source 24 may be wired to the power input of the electric motor and include one or more AC-to-DC rectifiers and transformers so as to rectify and step-down the AC power to low voltage DC power for use by the data acquisition device 10.

The above-described data acquisition devices 10 continuously or periodically develop sensor data and location data and transmit the data to the remote monitoring device. The remote monitoring device receives the sensor data and location data from the data acquisition devices and analyzes the data to determine when the motors are in need of repair or replacement. The remote monitoring device may also provide alerts to technicians or other persons if the monitored motors are in need of repair and/or replacement. For example, if the sensor of the data acquisition device is a vibration sensor, the remote monitoring device may monitor the sensor data to determine when the motor is experiencing a level of vibration that suggests the need of motor repair or replacement. The remote monitoring device may then provide an alert to a technician, along with location data for the motor, so that the technician can find the motor to repair and/or replace it.

The remote monitoring device may be any device capable of performing the functions described herein. In one embodiment, the remote monitoring device may be a web server that can be accessed by technicians and others via the Internet or other communications channel. In other embodiments, the remote monitoring device may be mobile phone or other portable electronic device that receives information from the data acquisition devices 10.

The web server embodiment of the remote monitoring device may be implemented with the computer system shown in FIG. 1. One embodiment of the computer system 12 includes a server computer 28 and one more personal computing devices 30 that exchange data via a communications network 32 and/or a wireless communications network 34. The equipment in the system 12 may be operated by any persons or entities. For example, in one embodiment, the computer 28 may be operated by or for an entity that provides motor monitoring and repair services and the personal computing devices 30 may be operated by or for motor installers or service technicians who repair or replace motors or other people involved with the operation or ownership of the motors.

The server computer 28 receives and stores the sensor data, location data, and/or other information transmitted from the data acquisition devices 10. The server computer 28 may also implement one or more computer programs for performing some of the functions described herein and may provide a web-based portal that can be accessed by the personal computing devices 30 and other devices.

Embodiments of the server computer 28 may include one or more servers running Windows; LAMP (Linux, Apache HTTP server, MySQL, and PHP/Perl/Python); Java; AJAX; NT; Novel Netware; Unix; or any other software system. The server computer 28 includes or has access to computer memory and other hardware and software for receiving, storing, accessing, and transmitting information as described below. The server computer 28 may also include conventional web hosting operating software, searching algorithms, an Internet connection, and is assigned a URL and corresponding domain name so that it can be accessed via the Internet in a conventional manner.

The personal computing devices 30 may be any devices used by motor installers, service technicians, plant operators, engineers, and/or other people involved with the operation or ownership of the motors 14. The personal computing devices 30 may be laptop computers, tablet computers, mobile phones, or similar devices as shown. Each personal computing device preferably includes or can access an Internet browser and a conventional Internet connection such as a wireless broadband connection, DSL converter, or ISDN converter so that it can receive communications from the server computer 28 via the communications networks 32, 34.

The communications network 32 is preferably the Internet but may be any other communications network such as a local area network, a wide area network, or an intranet. The communications network 34 may be a wireless network capable of supporting wireless communications such as the wireless networks operated by AT&T, Verizon, or Sprint. The wireless network may include conventional switching and routing equipment. The communications network 32 and wireless network 34 may also be combined or implemented with several different networks.

Embodiments of the present invention may also comprise one or more computer programs stored in or on computer-readable medium residing on or accessible by the server computer 28, the personal computing devices 32, or other components coupled with the system 12. The computer programs may comprise listings of executable instructions for implementing logical functions in the computers and can be embodied in any non-transitory computer-readable medium for use by or in connection with an instruction execution system, apparatus, or device, such as a computer-based system, processor-containing system, or other system that can fetch the instructions from the instruction execution system, apparatus, or device, and execute the instructions. In the context of this application, a “computer-readable medium” can be any non-transitory means that can contain, store, or communicate the programs. The computer-readable medium can be, for example, but not limited to, an electronic, magnetic, optical, electro-magnetic, infrared, or semi-conductor system, apparatus, or device. More specific, although not inclusive, examples of the computer-readable medium would include the following: an electrical connection having one or more wires, a portable computer diskette, a random access memory (RAM), a read-only memory (ROM), an erasable, programmable, read-only memory (EPROM or Flash memory), an optical fiber, and a portable compact disk read-only memory (CDROM).

The components of the computer system 12 illustrated and described herein are merely examples of equipment that may be used to implement embodiments of the present invention and may be replaced with other equipment without departing from the scope of the present invention.

The installation of use of the data acquisition devices 10 will now be summarized. Each of the above-described data acquisition devices 10 may be mounted on or near any electric motor, including those already in service. Each data acquisition device 10 continuously or periodically collects sensor data and location data and transmits it to the computer or other monitoring device. The sensor data may represent conditions of the motor 14, components driven by the motor, or devices separate from the motor.

In one embodiment, each data acquisition device transmits all collected sensor data and location data. In other embodiments, the data acquisition device only transmits the sensor data and location data when the sensor data is outside of a predetermined range. For example, the control unit 22 in the data acquisition device may compare the sensor data to a threshold level and only transmit the sensor data and the location data if the sensor data is above the threshold level.

The remote monitoring device receives and analyzes the sensor data to determine if the monitored motor is in need of repair. For example, the remote monitoring device may compare the received sensor data to a threshold level and determine that the motor is in need of repair if it exceeds the threshold level by a first amount and determine that the motor is in need of replacement if the sensor data exceeds the threshold level by a second, higher amount. The remote monitoring device may also provide an alert to a technician or other person when the motor is in need of repair and/or replacement.

For example, if the sensor of one of the data acquisition devices is a vibration sensor, the remote monitoring device may monitor the sensor data to determine when the motor is experiencing a level of vibration that suggests the need of motor repair or replacement. The remote computer may then send an alert to a technician, along with location data for the motor, so that the technician can find the motor to repair and/or replace it.

The remote monitoring device may also evaluate the received sensor data for trends that suggest the motor needs repair or replacement. For example, the remote monitoring device may compare recently received sensor data to previously received sensor data to see if the sensor data shows trends such as increasing motor vibrations, motor temperature, etc. that suggest the motor needs repair or replacement.

In other embodiments of the invention, the sensor data and the location data may be sent directly to a technician's mobile phone. The mobile phone may be programmed with an application that enables it to act as the remote monitoring device and receive and evaluate the sensor data to determine if motor repairs are needed.

Although the invention has been described with reference to the preferred embodiment illustrated in the attached drawing figures, it is noted that equivalents may be employed and substitutions made herein without departing from the scope of the invention as recited in the claims.

Having thus described the preferred embodiment of the invention, what is claimed as new and desired to be protected by Letters Patent includes the following:

1. A data acquisition device for an electric motor, the data acquisition device comprising:
a location determining component for determining a location of the motor and generating corresponding location data;
a sensor for sensing a condition of the motor or a component driven by the motor and generating sensor data;
a communication device;
control unit for receiving the location data from the location determining component and the sensor data from the sensor and for instructing the communication device to transmit at least portions of the location data and the sensor data to a remote monitoring device that is located at a different site than the electric motor; and
a power source for powering the location determining component, the sensor, the communication device, and the control unit.

2. The data acquisition device of claim 1, further comprising an input for receiving additional sensor data from a sensor that senses a condition of a device separate from the electric motor or the component driven by the motor, the control unit and the communication device being further operable to transmit at least portions of the additional sensor data to the remote monitoring device.

3. The data acquisition device of claim 1, wherein the location determining component is a global navigation satellite system receiver selected from the group consisting of a GPS, GLONASS, Galileo, and Beidou system receiver.

4. The data acquisition device of claim 1, wherein the sensor is a vibration sensor, a temperature sensor, a current sensor, a voltage sensor, a power sensor, a speed sensor, a pressure sensor, a flow sensor, or a motor flux sensor.

5. The data acquisition device of claim 1, wherein the communication device is a cellular phone transmitter or a peer-to-peer network transmitter.

6. The data acquisition device of claim 1, wherein the control unit includes a processor, integrated circuit, or application specific integrated circuit.

7. The data acquisition device of claim 1, wherein the power source is selected from the group consisting of a current transformer, a power scavenging flux coil, a battery, and a capacitor.

8. The data acquisition device of claim 1, wherein the control unit and the communication device periodically transmit the location data and the sensor data to the remote computing device.

9. The data acquisition device of claim 1, wherein the control unit only transmits the location data and the sensor data if the control unit determines the sensor data deviates from a selected threshold range.

10. The data acquisition device of claim 1, wherein the remote monitoring device is a web server.

11. The data acquisition device of claim 1, wherein the remote monitoring device is a mobile phone.

12. A data acquisition device for an electric motor, the data acquisition device comprising:
an input for communicating with a location determining component that determines a location near the electric motor and generates corresponding location data;
an input for communicating with a sensor that senses a condition of the motor, a component driven by the motor, or a device separate from the electric motor and that generates corresponding sensor data;
an input for communicating with a communication device;
a control unit for receiving the location data from the location determining component and the sensor data from the sensor and for instructing the communication device to transmit at least portions of the location data and the sensor data to a remote monitoring device for remote monitoring purposes; and
an input for receiving power from a power source for powering the control unit.

13. The data acquisition device of claim 12, wherein the power source is a passive power source for scavenging power from the motor.

14. The data acquisition device of claim 13, wherein the passive power source is a power scavenging transformer coil and a battery or a capacitor for storing power from the power scavenging flux coil.

15. The data acquisition device of claim 12, wherein the location determining component is a GNSS receiver selected from the group consisting of a GPS, GLONASS, Galileo and Beidou system receiver.

16. The data acquisition device of claim 12, wherein the sensor is a vibration sensor, a temperature sensor, a current sensor, a voltage sensor, a power sensor, a speed sensor, a pressure sensor, a flow sensor, or a motor flux sensor.

17. The data acquisition device of claim 12, wherein the communication device is a cellular phone transmitter or a peer-to-peer network transmitter.

18. A method for monitoring operation of an electric motor for repair, replacement, or monitoring purposes, the method comprising:
providing a data acquisition device to be attached to or near the electric motor;
receiving data from the data acquisition device at a remote monitoring device that is at a different site than the electric motor, the data including:
a) location data representative of a location of the data acquisition device, and
b) sensor data representative of a condition of the electric motor or a component driven by the electric motor;
analyzing the sensor data at the remote monitoring device; and
sending at least a portion of the sensor data, or data derived from the sensor data, from the remote computer system to another device for monitoring, data collection, maintenance or replacement purposes.

19. The method of claim 18, the data acquisition device comprising:
a location determining component for determining the location data;
a sensor for generating the sensor data;
a communication device;
control unit for receiving the location data and the sensor data from the location determining component and the sensor and for instructing the communication device to transmit the location data and the sensor data to the remote monitoring device; and
a power source for powering the location determining component, the sensor, the communication device, and the control unit.

20. The method of claim 19, further comprising the step of:
sending a notification from the remote monitoring device to a service person if the analysis of the sensor data indicates the motor is in need of service or replacement, the notification including the location of the motor.

21. A data acquisition device for an electric motor, the data acquisition device comprising:
a location determining component for determining a location of the motor and generating corresponding location data;
a communication device;
control unit for receiving the location data from the location determining component and for instructing the communication device to transmit at least portions of the location data to a remote monitoring device that is located at a different site than the electric motor; and
a power source for powering the location determining component, the communication device, and the control unit, wherein the power source is selected from the group consisting of a current transformer, a power scavenging flux coil, a battery, and a capacitor.

22. The data acquisition device of claim 21, further comprising a sensor for sensing a condition of the motor or a component driven by the motor and generating sensor data, wherein the control unit is operable for receiving the sensor data from the sensor and for instructing the communication device to transmit at least a portion of the sensor data along with the location data.

23. A data acquisition device for an electric motor, the data acquisition device comprising:
a location determining component for determining a location of the motor and generating corresponding location data;
a sensor for sensing a condition of the motor or a component driven by the motor and generating sensor data;
a communication device; and
control unit for receiving the location data from the location determining component and the sensor data from the sensor and for instructing the communication device to transmit at least portions of the location data and the sensor data to a remote monitoring device that is located at a different site than the electric motor.

24. The data acquisition device of claim 23, further comprising a power source for powering the location determining component, the sensor, the communication device, and the control unit, wherein the power source is selected from the group consisting of a current transformer, a power scavenging flux coil, a battery, and a capacitor.

25. A data acquisition device for an electric motor, the data acquisition device comprising:
a sensor for sensing a condition of the motor or a component driven by the motor and generating sensor data;
a communication device;
control unit for receiving the sensor data from the sensor and for instructing the communication device to transmit at least portions of the sensor data to a remote monitoring device that is located at a different site than the electric motor; and
a power source for powering the sensor, the communication device, and the control unit wherein the power source is selected from the group consisting of a current transformer, a power scavenging flux coil, a battery, and a capacitor.

26. The data acquisition device of claim 25, further comprising a location determining component for determining a location of the motor and generating corresponding location data, wherein the control unit is operable for receiving the location data from the location determining component and for instructing the communication device to transmit at least a portion of the location data along with the sensor data.
